(19) United States
(12) Patent Application Publication
(10) Pub. No.: US 2026/0068485 A1
(43) Pub. Date: Mar. 5, 2026

(54) DISPLAY DEVICE INCLUDING A FUNCTIONAL LAYER INSERTED INTO A GROOVE, ELECTRONIC DEVICE, AND METHOD FOR FABRICATING THE SAME

(71) Applicant: SAMSUNG DISPLAY CO., LTD., Yongin-Si (KR)

(72) Inventors: Jeong Moon LEE, Yongin-si (KR); Dae Hong KIM, Yongin-si (KR)

(21) Appl. No.: 19/220,323

(22) Filed: May 28, 2025

(30) Foreign Application Priority Data
Aug. 30, 2024 (KR) 10-2024-0117693

(51) Int. Cl. H10K 59/80; H10K 77/10; H10K 102/00

(52) U.S. Cl. CPC H10K 59/8722; H10K 77/111; H10K 2102/311

(57) ABSTRACT

A display device includes a substrate. The substrate may include a first surface and a second surface opposite to the first surface. A display element layer may be disposed on the first surface of the substrate. A groove may be formed within the second surface of the substrate. A functional layer may be disposed on the second surface of the substrate. At least a portion of the functional layer may be inserted into the groove.

### CROSS-REFERENCE TO RELATED APPLICATION

This application claims priority under 35 U.S.C. § 119 to Korean Patent Application No. 10-2024-0117693, filed on Aug. 30, 2024, in the Korean Intellectual Property Office, the disclosure of which is incorporated by reference herein in its entirety.

### TECHNICAL FIELD

The present disclosure relates to a display device and, more specifically, to a display device including a functional layer inserted into a groove, an electronic device, and a method of fabricating the same.

### DISCUSSION OF THE RELATED ART

An organic light-emitting display apparatus may include a substrate, a display element layer including display elements having variable luminance, and a functional layer. The functional layer may be disposed on a surface of the substrate. However, the bonding between the substrate and the functional layer may be such that the functional layer might not adhere to the surface of the substrate. Moreover, the raw material of the functional layer may overflow.

### SUMMARY

Embodiments of the present disclosure provide a display device including a functional layer inserted into a groove, an electronic device, and a method for fabricating the same. Inserting the functional layer into the groove ensures better bonding between a substrate and a functional layer, while preventing raw material of the functional layer from overflowing.

According to an embodiment of the present disclosure, there is provided a display device including a substrate. The substrate may include a first surface and a second surface opposite to the first surface. A display element layer may be disposed on the first surface of the substrate. A groove may be formed within the second surface of the substrate. A functional layer may be disposed on the second surface of the substrate. At least a portion of the functional layer may be inserted into the groove.

According to an embodiment of the present disclosure, there is provided a method for fabricating a display device. The method includes preparing a substrate. A display element layer may be formed on a first surface of the substrate. A groove may be formed within a second surface of the substrate. The second surface of the substrate may be opposite to the first surface of the substrate. A functional layer may be formed by spreading an organic material on the second surface of the substrate. At least a portion of the functional layer may be consequently inserted into the groove.

According to an embodiment of the present disclosure, there is provided an electronic device including a display device. The display device may include a screen. The display device may include a substrate, and the substrate may have a first surface and second surface opposite to the first surface. A display element layer may be disposed on the first surface of the substrate. A groove may be formed within the second surface of the substrate. A functional layer may be disposed on the second surface of the substrate. At least a portion of the functional layer may be inserted into the groove.

### BRIEF DESCRIPTION OF THE DRAWINGS

The above and other features of the present disclosure will become apparent from the following description of the embodiments, taken in conjunction with the accompanying drawings, in which:

FIG. 1 is a perspective view showing a display device according to an embodiment;

FIG. 2 is a cross-sectional view showing the display device according to an embodiment;

FIG. 3 is a plan view of a display panel according to an embodiment;

FIG. 4 is a cross-sectional view taken along line I-I′ of FIG. 3;

FIG. 5 is a diagram showing a rear surface of a display panel of FIG. 4;

FIG. 6 is a diagram showing a display panel from which the functional layer of FIG. 5 is removed;

FIGS. 7, 8, 9, 10, and 11 are diagrams showing cross-sections of a display panel according to some embodiments;

FIGS. 12, 13, 14, and 15 are diagrams for explaining a method for fabricating a display device according to an embodiment.

FIG. 16 is a block diagram of an electronic device according to an embodiment.

FIGS. 17, 18, and 19 are schematic diagrams of electronic devices according to various embodiments.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not necessarily be construed as limited to the embodiments set forth herein. Rather, these embodiments are provided so that this disclosure will be thorough and complete, and will fully convey the scope of the invention to those skilled in the art.

Embodiments of the present disclosure are described with the understanding that when a layer is referred to as being “on” another layer or substrate, it may be disposed directly on the other layer or substrate, or intervening layers may also be present. Same components are referenced by the same reference numbers throughout the specification. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

Although the terms “first”, “second”, etc. may be used herein to describe various elements, these elements, should not necessarily be limited by these terms. These terms may be used to distinguish one element from another element. Thus, a first element discussed below may be termed a second element without departing from the teachings of one or more embodiments. The description of an element as a “first” element might not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. Those skilled in the art will recognize that the present disclosure can be practiced technically using various interactions and operations. Embodiments of the present disclosure can be practiced individually or in combination thereof.

Hereinafter, embodiments will be described in detail with reference to the accompanying drawings.

The present disclosure focuses on ensuring better bonding between a substrate and a functional layer, while preventing an overflow of the raw material of the functional layer from an edge of the substrate.

Traditional designs may include a substrate and a functional layer. However, the bonding between the functional layer and the substrate may be such that the functional layer might not adhere to the surface of the substrate. For example, the functional layer might not stay on the surface of the functional layer. Moreover, the raw material of the functional layer may overflow from an edge of the substrate.

To resolve these challenges, grooves may be defined on the surface of the substrate, and at least a portion of the functional layer may be inserted into the grooves. The disclosed approach may ensure better bonding between a functional layer and a substrate, and may also prevent the overflow of the raw material of the functional layer from an edge of the substrate.

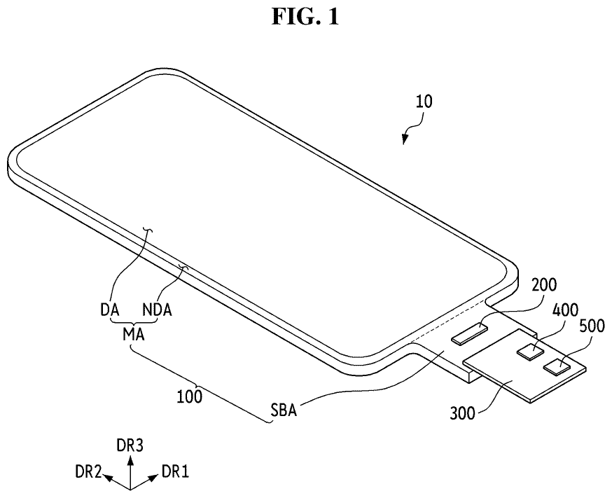

FIG. 1 is a perspective view showing a display device according to an embodiment.

Referring to FIG. 1, a display device 10 may be applied to portable electronic devices such as a mobile phone, a smartphone, a tablet computer, a mobile communication terminal, an electronic organizer, an electronic book, a portable multimedia player (PMP), a navigation system, an ultra-mobile PC (UMPC), or the like. In some embodiments, the display device 10 may be applied as a display unit of a television, a laptop, a computer monitor, a digital billboard, or an Internet-of-Things (IoT) device. In some embodiments, the display device 10 may be applied to wearable devices such as a smartwatch, a glass-type display, or a head-mounted display (HMD).

In some embodiments, the display device 10 may have a planar shape similar to a quadrilateral shape. For example, the display device 10 may have a quadrilateral shape having a pair of short sides extending primarily in a first direction DR1 and a pair of long sides extending primarily in a second direction DR2. A corner where the short side in the first direction DR1 and the long side in the second direction DR2 meet may be right-angled or rounded with a predetermined curvature. The planar shape of the display device 10 is not necessarily limited to a quadrilateral shape, and may be formed in a shape similar to another polygonal shape, a circular shape, or an elliptical shape.

The display device 10 may include a display panel 100, a display driver 200, a circuit board 300, a touch driver 400, and a power supply unit 500.

The display panel 100 may include a main region MA and a sub-region SBA.

The main region MA may include a display area DA including pixels displaying an image and a non-display area NDA disposed around the display area DA. The display area DA may emit light from a plurality of emission areas or from a plurality of opening areas. In some embodiments, the display panel 100 may include a pixel circuit including switching elements, a pixel-defining layer defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro-LED, but is not necessarily limited thereto.

The non-display area NDA may be an area outside the display area DA. The non-display area NDA may be defined as an area on the edge of the main region MA of the display panel 100. The non-display area NDA may include a gate driver that supplies gate signals to the gate lines, and fan-out lines that connect the display driver 200 to the display area DA.

The sub-region SBA may extend from one side of the main region MA. The sub-region SBA may include a flexible material which may be bent, folded, or rolled to a noticeable extent without cracking or otherwise sustaining damage. For example, when the sub-region SBA is bent, the sub-region SBA may overlap the main region MA in a thickness direction (e.g., a third direction DR3). The sub-region SBA may include the display driver 200 and a pad portion connected to the circuit board 300. In some embodiments, the sub-region SBA may be omitted, and the display driver 200 and the pad portion may be arranged in the non-display area NDA.

The display driver 200 may output signals and voltages for driving the display panel 100. The display driver 200 may supply data voltages to data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. In some embodiments, the display driver 200 may be disposed in the sub-region SBA, and may overlap the main region MA in the thickness direction (third direction DR3) by bending of the sub-region SBA. In some embodiments, the display driver 200 may be mounted on the circuit board 300.

The circuit board 300 may be attached to the pad portion of the display panel 100 by using an anisotropic conductive film (ACF). The circuit board 300 may include lead lines, and the lead lines of the circuit board 300 may be electrically connected to a pad portion of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch-sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a predetermined frequency. The touch driver 400 may calculate whether an input is made and input coordinates based on an amount of change in capacitance between the plurality of touch electrodes. The touch driver 400 may be formed of an integrated circuit (IC).

The power supply unit 500 may be disposed on the circuit board 300 to supply a power voltage to the display driver 200 and the display panel 100. The power supply unit 500 may generate a driving voltage to supply it to a driving voltage line, generate an initialization voltage to supply it to an initialization voltage line, generate a reference voltage to supply it to a reference voltage line, and generate a common voltage to supply it to a common voltage line. The common voltage of the common voltage line may be supplied to a common electrode common to light-emitting elements of a plurality of pixels. The driving voltage may be a high potential voltage for driving the light-emitting element, and the common voltage may be a low potential voltage for driving the light-emitting element.

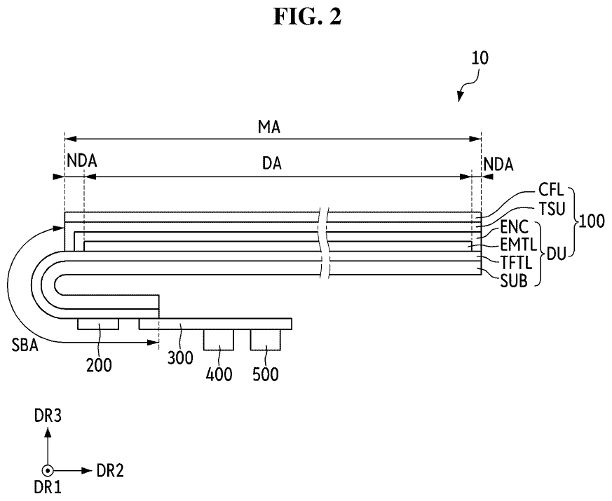

FIG. 2 is a cross-sectional view showing the display device according to an embodiment.

Referring to FIG. 2, the display panel 100 may include a display unit DU, a touch sensing unit TSU, and a color filter layer CFL. The display unit DU may include a substrate SUB, a thin film transistor layer TFTL, a display element layer EMTL, and an encapsulation layer ENC.

The substrate SUB may be a base substrate or a base member. The substrate SUB may be a flexible substrate which may be bent, folded, or rolled to a noticeable extent without cracking or otherwise sustaining damage. For example, the substrate SUB may include a polymer resin such as polyimide (PI), but is not necessarily limited thereto. In some embodiments, the substrate SUB may include a glass material or a metal material.

The thin film transistor layer TFTL may be disposed on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. In some embodiments, when the gate driver is formed on one side of the non-display area NDA of the display panel 100, the gate driver may include thin film transistors.

The thin film transistor layer TFTL may be disposed in the display area DA, the non-display area NDA, and the sub-region SBA. In some embodiments, thin film transistors, gate lines, data lines, and power lines of each of the pixels of the thin film transistor layer TFTL may be disposed in the display area DA. Gate control lines and fan-out lines of the thin film transistor layer TFTL may be disposed in the non-display area NDA. The lead lines of the thin film transistor layer TFTL may be disposed in the sub-region SBA.

The display element layer EMTL may be disposed on the thin film transistor layer TFTL. The display element layer EMTL may include a plurality of light emitting elements in which a pixel electrode, a light emitting layer, and a common electrode are sequentially stacked to emit light, and a pixel-defining layer defining pixels. The plurality of light emitting elements of the display element layer EMTL may be disposed in the display area DA.

In some embodiments, the light emitting layer may be an organic light emitting layer including an organic material. The light emitting layer may include a hole-transporting layer, an organic light emitting layer, and an electron-transporting layer. When the pixel electrode receives a predetermined voltage through the thin film transistor of the thin film transistor layer TFTL and the common electrode receives the cathode voltage, holes and electrons may be transferred to the organic light emitting layer through the hole transporting layer and the electron transporting layer, respectively. The holes and electrons may be combined with each other to emit light in the organic light-emitting layer. In some embodiments, the pixel electrode may be an anode electrode, and the common electrode may be a cathode electrode, but the present disclosure is not necessarily limited thereto.

In some embodiments, the plurality of light emitting elements may include a quantum dot light emitting diode including a quantum dot light emitting layer, an inorganic light emitting diode including an inorganic semiconductor, or a micro light emitting diode.

The encapsulation layer ENC may cover the top surface and the side surface of the display element layer EMTL, and may protect the display element layer EMTL. The encapsulation layer ENC may include at least one inorganic layer and at least one organic layer for encapsulating the display element layer EMTL.

The touch sensing unit TSU may be disposed on the encapsulation layer ENC. The touch sensing unit TSU may include a plurality of touch electrodes for sensing a user's touch in a capacitive manner, and touch lines connecting the plurality of touch electrodes to the touch driver 400. For example, the touch-sensing unit TSU may sense the user's touch by using a mutual capacitance method or a self-capacitance method.

In some embodiments, the touch sensing unit TSU may be disposed on a separate substrate disposed on the display unit DU. For example, the substrate supporting the touch sensing unit TSU may be a base member that encapsulates the display unit DU.

The plurality of touch electrodes of the touch sensing unit TSU may be disposed in a touch sensor area overlapping the display area DA. The touch lines of the touch sensing unit TSU may be disposed in a touch peripheral area that overlaps the non-display area NDA.

The color filter layer CFL may be disposed on the touch sensing unit TSU. The color filter layer CFL may include a plurality of color filters respectively corresponding to the plurality of emission area. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent color distortion caused by the reflection of the external light.

Since the color filter layer CFL is directly disposed on the touch sensing unit TSU, the display device 10 might not require a separate substrate for the color filter layer CFL. Therefore, the thickness of the display device 10 may be relatively reduced.

The sub-region SBA of the display panel 100 may extend from one side of the main region MA. The sub-region SBA may include a flexible material which may be bent, folded, or rolled to a noticeable extent without cracking or otherwise sustaining damage. For example, when the sub-region SBA is bent, the sub-region SBA may overlap the main region MA in a thickness direction (third direction DR3). The sub-region SBA may include the display driver 200 and the pad portion electrically connected to the circuit board 300.

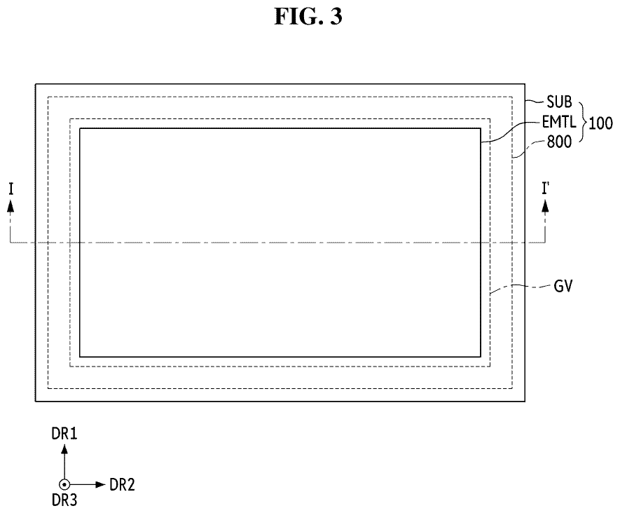

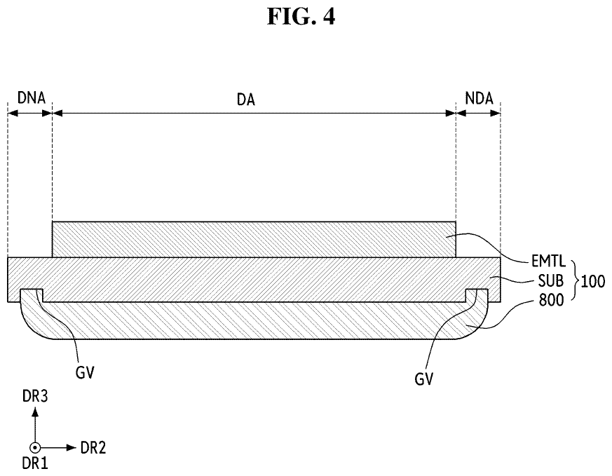

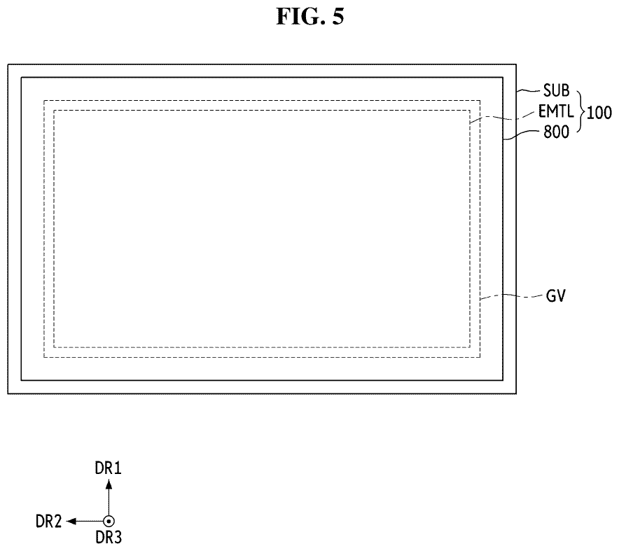

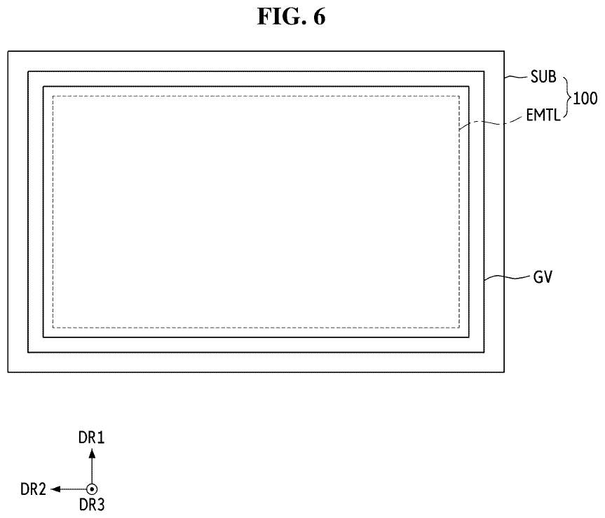

FIG. 3 is a plan view illustrating a display panel 100 according to an embodiment, and FIG. 4 is a cross-sectional view taken along line I-I′ of FIG. 3. FIG. 5 is a diagram showing a rear surface of the display panel 100 of FIG. 4, and FIG. 6 is a diagram showing the display panel 100 from which a functional layer 800 of FIG. 5 is removed. In an embodiment, FIG. 3 may be, for example, a plan view with respect to the display panel 100 of FIG. 1.

As shown in FIGS. 3 and 4, in some embodiments, the display panel 100 may include a functional layer 800, a substrate SUB, and a display element layer EMTL. Meanwhile, in some embodiments, the display panel 100 of FIGS. 3 and 4 may further include a thin film transistor layer TFTL, an encapsulation layer ENC, a touch sensing unit TSU, and a color filter layer CFL of FIG. 2 described above. For example, the thin film transistor layer TFTL may be further disposed between the substrate SUB and the display element layer EMTL of FIG. 3, and the encapsulation layer ENC, the touch sensing unit TSU, and the color filter layer CFL may be further disposed on the display element layer EMTL of FIG. 3.

In an embodiment, a substrate SUB may include a first surface and a second surface. The display element layer EMTL may be disposed on the first surface (e.g., top surface) of the substrate SUB, and the functional layer 800 may be disposed on the second surface (e.g., rear surface) of the substrate SUB. In an embodiment, the first surface and the second surface of the substrate SUB may face each other in a third direction DR3. In other words, the first surface of the substrate SUB may be opposite to the second surface of the substrate SUB. The substrate SUB may be disposed between the functional layer 800 and the display element layer EMTL. In an embodiment, the first surface of the substrate SUB may include an interface between the substrate SUB and the display element layer EMTL, and the second surface of the substrate SUB may include an interface between the substrate SUB and the functional layer 800.

The display element layer EMTL may be disposed in the display area DA of the substrate SUB on the first surface of the substrate SUB.

In an embodiment, the functional layer 800 may be disposed on the second surface of the substrate SUB. In an embodiment, the functional layer 800 may overlap the display area DA of the substrate SUB and the non-display area NDA of the substrate SUB. In some embodiments, the functional layer 800 may be disposed on the second surface of the substrate SUB to overlap the display area DA and partially overlap the non-display area NDA of the substrate SUB. The functional layer 800 may prevent reflection of light through the second surface of the substrate SUB and may protect the display panel 100 from impact or contact. In addition, the functional layer 800 may further include a heat dissipation function. Alternatively, a separate heat dissipation sheet may be further disposed on the functional layer 800. In an embodiment, the functional layer 800 may include an organic material such as resin.

A groove GV may be formed within the second surface of the substrate SUB. From a plan view as shown in FIGS. 3, 5, and 6, the groove GV may be formed in the non-display area NDA of the substrate SUB and within the second surface of the substrate SUB. In some embodiments, the groove GV may be formed to overlap the non-display area NDA of the substrate SUB. In other embodiments, the groove GV may be formed to only partially overlap the non-display area NDA of the substrate SUB. In a plan view, the groove GV may surround the display area DA (or the display element layer EMTL) of the substrate SUB. In some embodiments, the groove GV may be proximate to the display area DA (or the display element layer EMTL) of the substrate SUB. In some embodiments, the groove GV may have a closed curve shape proximate to the display area DA (or the display element layer EMTL) of the substrate SUB.

From a cross-sectional view as shown in FIG. 4, the groove GV may be recessed from the second surface of the substrate SUB toward one side of the substrate SUB. In an embodiment, the groove GV may be recessed from the second surface of the substrate SUB toward the first surface of the substrate. In some embodiments, as shown in FIG. 4, the groove GV may have a square cross-section.

In some embodiments, at least a portion of the functional layer 800 may be disposed or inserted into the groove GV of the substrate SUB. For example, the edge of the functional layer 800 may be inserted into the groove GV of the substrate SUB. Accordingly, better bonding between the functional layer 800 and the substrate SUB may be ensured. In addition, impact resistance at the edge of the substrate SUB may be increased.

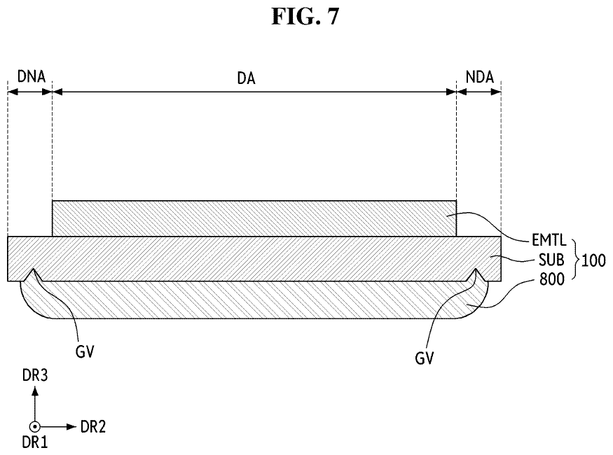

FIG. 7 is a diagram showing a cross-section of a display panel 100 according to an embodiment.

The display panel 100 of FIG. 7 is different from the display panel 100 of FIG. 4 described above, and the difference in the cross-sectional shape of the groove GV is described below. To the extent that an element is not described in detail with respect to this figure, it may be understood that the element is at least similar to a corresponding element that has been described elsewhere within the present disclosure.

As shown in FIG. 7, the groove GV may have a cross-section in the shape of an isosceles triangle.

From a plan view, the groove GV of FIG. 7 may have a closed curve shape proximate to the display area DA (or the display element layer EMTL) of the substrate SUB (see FIG. 3).

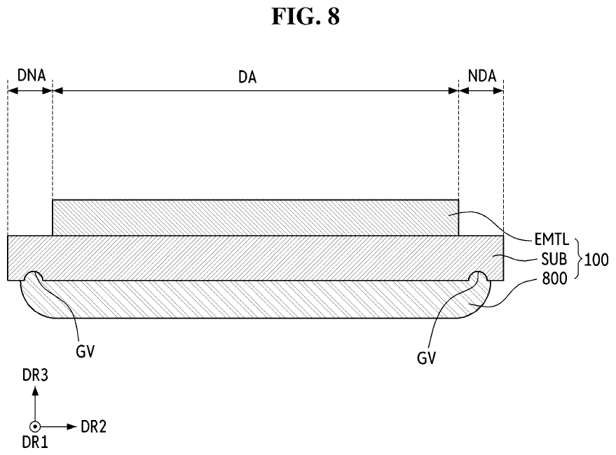

FIG. 8 is a diagram showing a cross-section of a display panel 100 according to an embodiment.

The display panel 100 of FIG. 8 is different from the display panel 100 of FIG. 4 described above, and the difference in the cross-sectional shape of the groove GV is described below. To the extent that an element is not described in detail with respect to this figure, it may be understood that the element is at least similar to a corresponding element that has been described elsewhere within the present disclosure.

As shown in FIG. 8, the groove GV may have a rounded cross-section. In some embodiments, the groove GV may have a parabolic cross-section.

From a plan view, the groove GV of FIG. 8 may have a closed curve shape proximate to the display area DA (or the display element layer EMTL) of the substrate SUB (see FIG. 3).

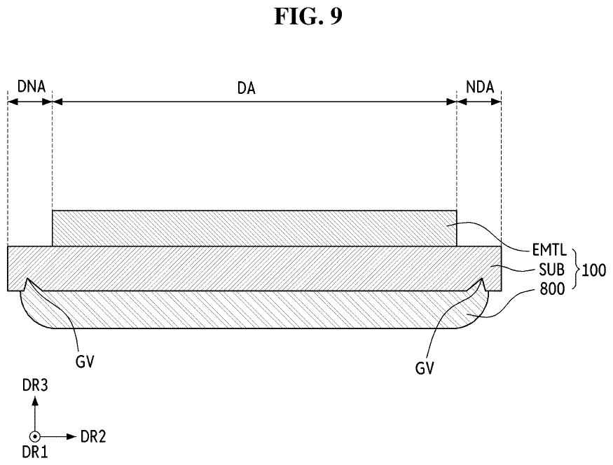

FIG. 9 is a diagram showing a cross-section of a display panel 100 according to an embodiment.

The display panel 100 of FIG. 9 is different from the display panel 100 of FIG. 4 described above, and the difference in the cross-sectional shape of the groove GV is described below. To the extent that an element is not described in detail with respect to this figure, it may be understood that the element is at least similar to a corresponding element that has been described elsewhere within the present disclosure.

As shown in FIG. 9, the groove GV may have a cross-section in the shape of an acute triangle.

From a plan view, the groove GV of FIG. 9 may have a closed curve shape proximate to the display area DA (or the display element layer EMTL) of the substrate SUB (see FIG. 3).

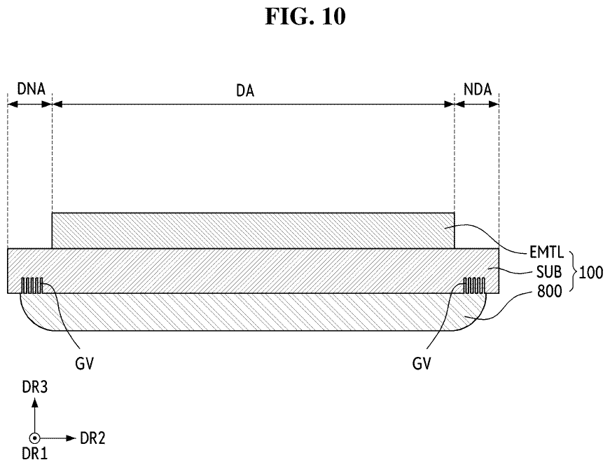

FIG. 10 is a diagram showing a cross-section of a display panel 100 according to an embodiment.

The display panel 100 of FIG. 10 is different from the display panel 100 of FIG. 4 described above, and the difference in the cross-sectional shape of the groove GV is described below. To the extent that an element is not described in detail with respect to this figure, it may be understood that the element is at least similar to a corresponding element that has been described elsewhere within the present disclosure.

As shown in FIG. 10, a plurality of grooves GV may be formed within the second surface of the substrate SUB. In an embodiment, the grooves GV may be provided in plural. Each groove GV may have the same depth, or at least two grooves GV may have different depths. In an embodiment, the depth of the groove GV may be, for example, the depth of the groove GV in the third direction DR3.

From a plan view, each groove GV of FIG. 10 may have a closed curve shape proximate to the display area DA (or the display element layer EMTL) of the substrate SUB (see FIG. 3). In an embodiment, the plurality of grooves GV may have a size that is larger toward the edge of the substrate SUB. In other words, the plurality of grooves GV may have longer lengths nearing toward the edge of the substrate SUB. In some embodiments, a depth of a single groove among a plurality of the grooves may be larger than a width of the same single groove among the plurality of the grooves.

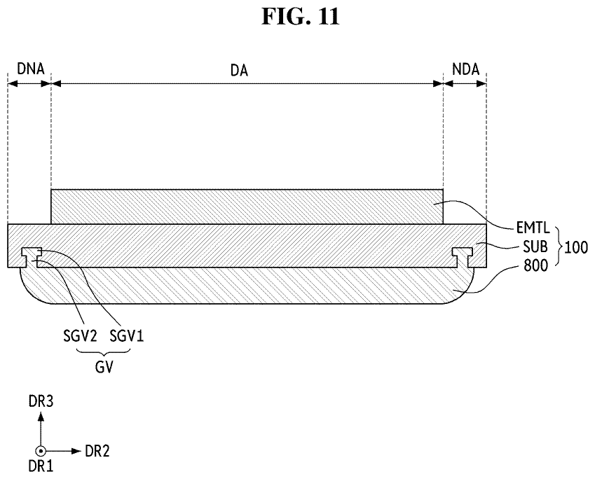

FIG. 11 is a diagram showing a cross-section of a display panel 100 according to an embodiment.

The display panel 100 of FIG. 11 is different from the display panel 100 of FIG. 4 described above, and the difference in the cross-sectional shape of the groove GV is described below. To the extent that an element is not described in detail with respect to this figure, it may be understood that the element is at least similar to a corresponding element that has been described elsewhere within the present disclosure.

As shown in FIG. 11, the groove GV may include a plurality of sub-grooves SGV1 and SGV2 having different widths. For example, as shown in FIG. 11, the groove GV may have a first sub-groove SGV1 and a second sub-groove SGV2, and the width of the first sub-groove SGV1 may differ from the width of the second sub-groove SGV2. In an embodiment, the groove GV may include a plurality of sub-grooves, and at least two sub-grooves of the plurality of the sub-groove may have different widths. In an embodiment, the width of the groove GV may be a size in a second direction DR2.

The first sub-groove SGV1 and the second sub-groove SGV2 may be arranged along the third direction DR3 and may overlap along the third direction DR3. In an embodiment, the first sub-groove SGV1 and the second sub-groove SGV2 may be connected to each other. In the third direction DR3, the first sub-groove SGV1, among the first and second sub-grooves SGV1 and SGV2, may be formed closer to the first surface of the substrate SUB. For example, among the first sub-groove SGV1 and the second sub-groove SGV2, the first sub-groove SGV1 may be formed closer to the display element layer EMTL. In an embodiment, a distance between the first sub-groove SGV1 and the first surface of the substrate may be smaller than a distance between the second sub-groove SGV2 and the first surface of the substrate. The width of the second sub-groove SGV2 may be smaller than the width of the first sub-groove SGV1. The functional layer 800 may be disposed in or inserted into the first sub-groove SGV1 and the second sub-groove SGV2. Since the edge of the functional layer 800 disposed in the first sub-groove SGV1 has a larger width than the edge of the functional layer 800 disposed in the second sub-groove SGV2, the functional layer 800 inserted into the groove GV including the first sub-groove SGV1 and the second sub-groove SGV2 may have a shape that is difficult to be separated in the direction opposite to the third direction DR3. Accordingly, better bonding between the functional layer 800 and the substrate SUB is ensured.

From a plan view, the groove GV of FIG. 11 may have a closed curve shape proximate to the display area DA (or the display element layer EMTL) of the substrate SUB (see FIG. 3). For example, each of the first sub-groove SGV1 and the second sub-groove SGV2 may have a closed curve shape proximate to the display area DA (or the display element layer EMTL) of the substrate SUB (see FIG. 3).

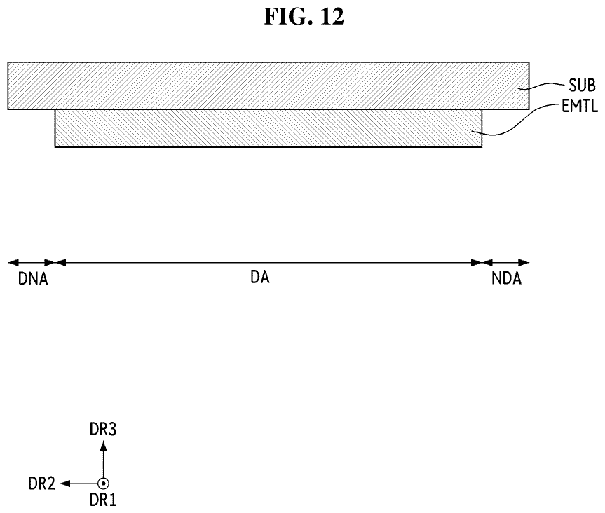

FIGS. 12, 13, 14, and 15 are diagrams for explaining a method for fabricating a display device according to an embodiment.

First, as shown in FIG. 12, a substrate SUB is prepared. A display element layer EMTL may be disposed on a first surface of the substrate SUB. Thereafter, the substrate SUB may be flipped so that the second surface of the substrate SUB faces the other or upper side.

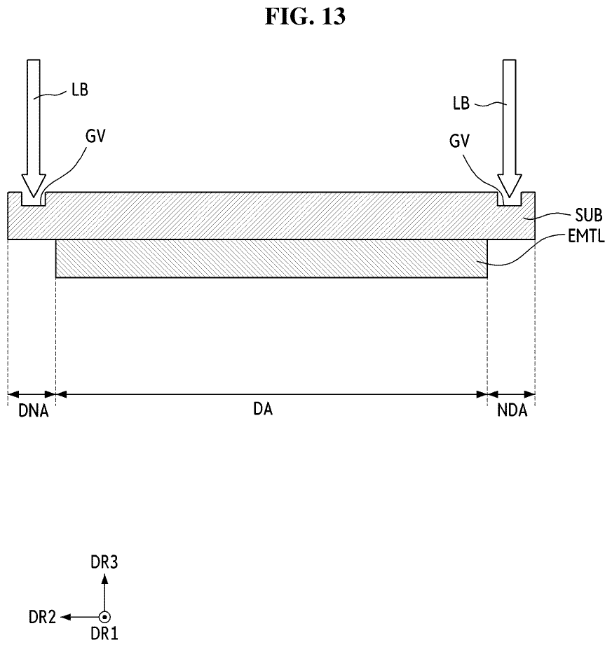

Next, as shown in FIG. 13, a laser beam LB may be cast on the second surface of the substrate SUB. For example, the laser beam LB may be cast in the non-display area NDA of the substrate SUB on the second surface of the substrate SUB. Accordingly, a groove GV may be formed at the edge of the second surface of the substrate SUB.

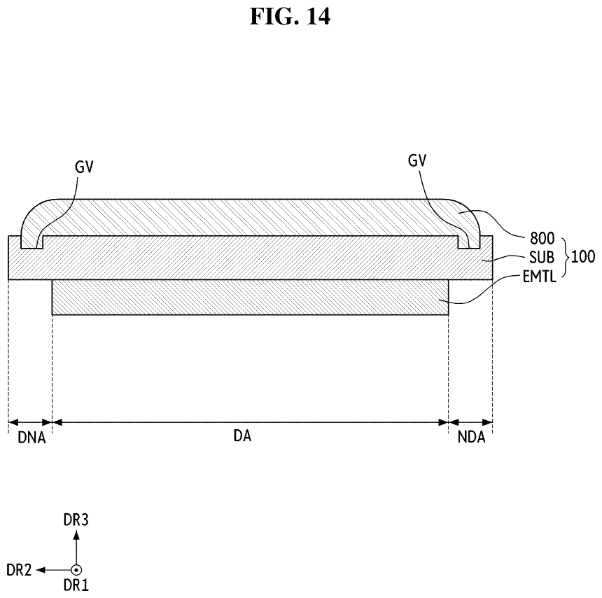

Thereafter, as shown in FIG. 14, an organic material which is the raw material of a functional layer 800 may be applied on the second surface of the substrate SUB. The organic material may be applied in a dot form on the second surface of the substrate SUB. As time passes, the organic material on the second surface of the substrate SUB may spread to the edge of the substrate SUB. At the edge of the substrate SUB, the organic material may then be inserted into the groove GV. Accordingly, the functional layer 800, as shown in FIG. 14, may be formed. In an embodiment, at least a portion of the functional layer 800 may be disposed in the groove GV. As the edge of the functional layer 800 is inserted into the groove GV at the edge of the substrate SUB, the organic material may be prevented from invading a cut area of the edge. Accordingly, the cut area of the substrate SUB may be prevented from being contaminated by the raw material of the functional layer, which may be an organic material. In addition, the organic material may be prevented from overflowing from the edge of the substrate SUB and/or the cut area.

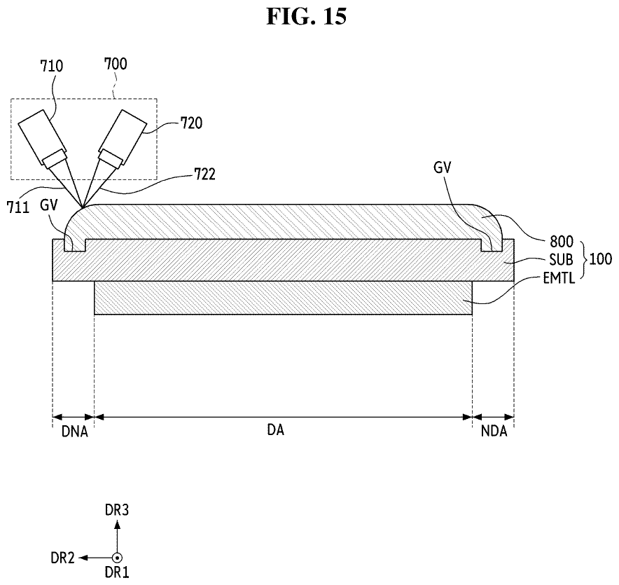

Subsequently, as shown in FIG. 15, the thickness of the functional layer 800 may be measured (or detected) through an optical device 700. For example, the optical device 700 may include a radiation unit 710 that casts light 711 and a light receiving unit 720 that receives reflected light 722. The light 711 emitted from the radiation unit 710 and cast on the functional layer 800 may be reflected and incident on the light receiving unit 720. The optical device 700 may detect the thickness of the functional layer 800 based on the light 722 incident on the light receiving unit 720. For example, the optical device 700 may determine whether the functional layer 800 completely fills in the groove GV or not, based on the thickness of the functional layer 800 filled in the groove GV. Thus, the optical device 700 may determine, for example, whether the application of the functional layer 800 is defective.

According to the embodiments of the disclosure, the display device disclosed herein may be applied to various electronic devices. The electronic device according to an embodiment includes the disclosed display device and may further include modules or devices having additional functions in addition to the display device.

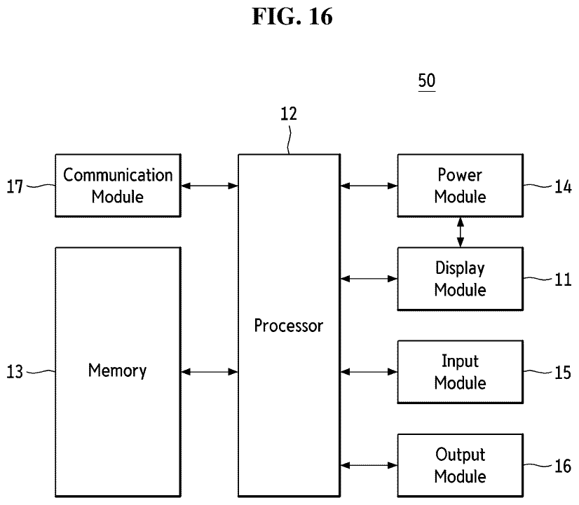

FIG. 16 is a block diagram of an electronic device according to an embodiment. Referring to FIG. 16, the electronic device 50, according to an embodiment, may include a display module 11, a processor 12, a memory 13, and a power module 14. The electronic device 50 may further include an input module 15, a non-image output module 16 and/or a communication module 17.

The electronic device 50 may output information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 15 may provide input information to the processor 12 and/or the display module 11. The non-image output module 16 may receive information other than images transmitted from the processor 12, such as sound, haptics, and light, and provide the information to the user. The communication module 17 may be responsible for transmitting and receiving information between the electronic device 50 and an external device, and may include a receiving unit and a transmitting unit.

At least one of the components of the electronic device 50 described in the disclosure may be included in the display device, according to the embodiments described herein. In addition, some of the individual modules functionally included in one module may be included in the display device, and others may be provided separately from the display device. For example, the display device may include a display module 11, and the processor 12, memory 13, and power module 14 may be provided in the form of other devices within the electronic device 50 other than the display device.

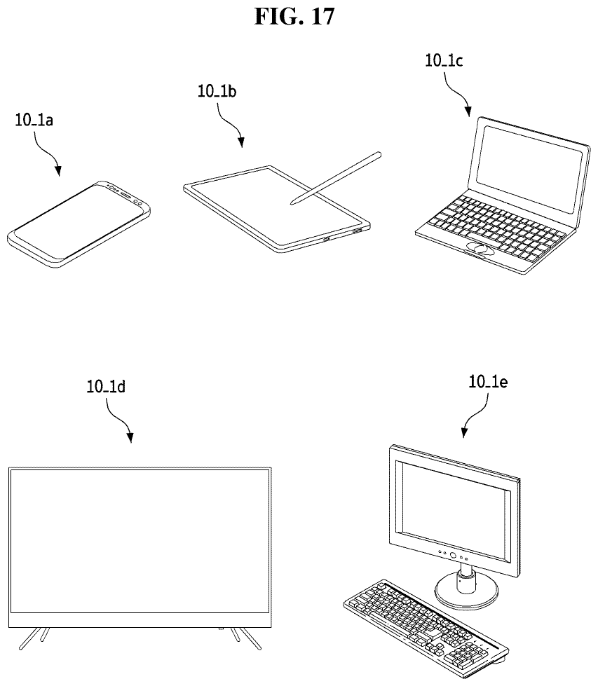

FIGS. 17, 18, and 19 are schematic diagrams of electronic devices according to various embodiments. FIGS. 17, 18, and 19 illustrate examples of various electronic devices to which the display device, according to the embodiments disclosed herein, is applied.

FIG. 17 illustrates a smartphone 10_1a, a tablet computer 10_1b, a laptop 10_1c, a TV 10_1d, and a computer monitor 10_1e, as examples of electronic devices.

In addition to the display module 11, the smartphone 10_1a may include an input module such as a touch sensor and a communication module. The smartphone 10_1a may process information received through the communication module or other input modules and display the information through the display module of the display device.

In some embodiments, the tablet computers10_1b, laptops 10_1c, TVs 10_1d, or computer monitors 10_1e may also include display modules and input modules similar to smartphones 10_1a, and may additionally include communication modules in some cases.

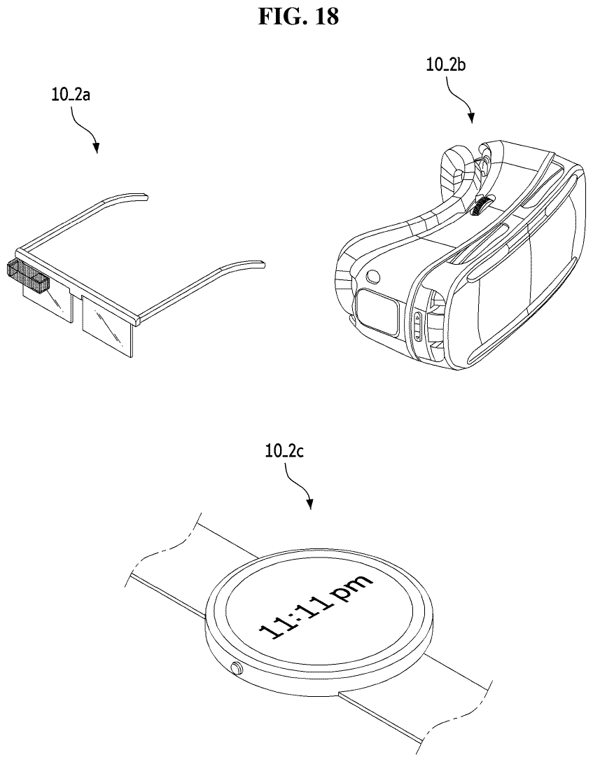

FIG. 18 shows examples of electronic devices including display modules being applied to wearable electronic devices. For example, the wearable electronic device may be a smart glass 10_2a, a head-mounted display 10_2b, or a smartwatch 10_2c, etc.

The smart glasses 10_2a or the head-mounted display 10_2b may include a display module that emits a display image and a reflector that reflects the emitted display screen and provides it to the users, thereby providing a virtual reality or augmented reality screen to the user.

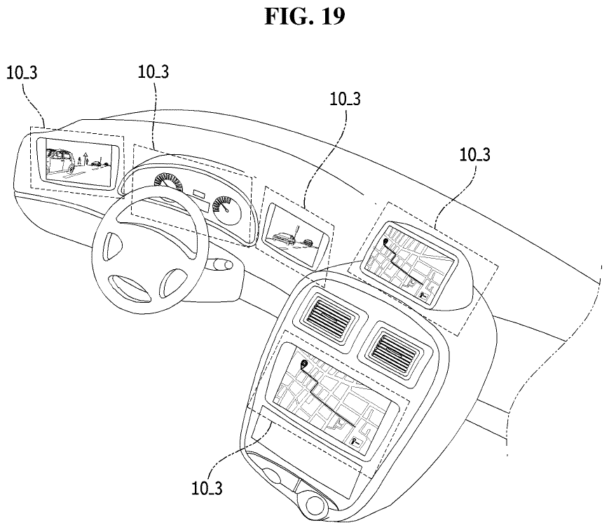

The smartwatch 10_2c may include a biometric sensor as an input device, and may provide biometric information recognized by the biometric sensor to the user through the display module. In an embodiment, an electronic device including a display module may be applied to a vehicle, as illustrated in FIG. 19. For example, the electronic device 10_3 may be applied to a dashboard, center fascia, etc. of a vehicle, or may be applied to a CID (Center Information Display) placed on a dashboard of a vehicle, or a room mirror display replacing a side mirror.

Those skilled in the art will recognize that the present disclosure can be practiced in other specific ways without departing from its technical spirit or essential characteristics. Therefore, the described embodiments should be regarded as illustrative rather than being restrictive in all aspects. Although embodiments of the present disclosure have been described with reference to the accompanying drawings, the disclosure is not necessarily limited to these embodiments and may be implemented in various forms.

What is claimed is:

1. A display device, comprising:
a substrate including a first surface and a second surface opposite to the first surface;
a display element layer disposed on the first surface of the substrate;
a groove formed within the second surface of the substrate; and
a functional layer disposed on the second surface of the substrate, wherein at least a portion of the functional layer inserted into the groove.

2. The display device of claim 1,
wherein the groove is formed within the second surface of the substrate to overlap a non-display area of the substrate.

3. The display device of claim 1,
wherein the groove is recessed from the second surface of the substrate toward the first surface of the substrate.

4. The display device of claim 1,
wherein, in a plan view, the groove is proximate to a display area of the substrate.

5. The display device of claim 1,
wherein the groove has a square cross-section.

6. The display device of claim 1,
wherein the groove has a triangular cross-section.

7. The display device of claim 1,
wherein the groove has a rounded cross-section.

8. The display device of claim 1,
wherein the groove is provided in plural.

9. The display device of claim 8,
wherein at least two of the plurality of the grooves have different depths.

10. The display device of claim 1, wherein:
the groove comprises a plurality of sub-grooves, and at least two sub-grooves of the plurality of sub-grooves have different widths.

11. The display device of claim 10, wherein:
the plurality of sub-grooves includes a first sub-groove and a second sub-groove, and
a width of the first sub-groove is different from a width of the second sub-groove.

12. The display device of claim 11,
wherein the width of the first sub-groove is larger than the width of the second sub-groove.

13. The display device of claim 12,
wherein a distance between the first sub-groove and the first surface of the substrate is smaller than a distance between the second sub-groove and the first surface of the substrate.

14. The display device of claim 1,
wherein the functional layer includes an organic material.

15. The display device of claim 1,
wherein the functional layer is disposed on the second surface of the substrate to overlap a display area of the substrate and a non-display area of the substrate.

16. A method for fabricating a display device, the method comprising:
preparing a substrate;
forming a display element layer on a first surface of the substrate;
forming a groove within a second surface of the substrate, wherein the second surface of the substrate is opposite to the first surface of the substrate; and
forming a functional layer including an organic material by spreading the organic material on the second surface of the substrate, wherein at least a portion of the functional layer is inserted into the groove.

17. The method of claim 16, wherein:
the groove is formed within the second surface of the substrate to overlap a non-display area of the substrate,
the groove, in a plan view, is formed proximate to a display area of the substrate, and
the groove is recessed from the second surface of the substrate toward one side of the substrate.

18. The method of claim 16, further comprising:
inspecting a thickness of the functional layer.

19. An electronic device, comprising:
a display device including a screen, the display device comprising:
a substrate including a first surface and a second surface opposite to the first surface;
a display element layer disposed on the first surface of the substrate;
a groove formed within the second surface of the substrate; and
a functional layer disposed on the second surface of the substrate, wherein at least a portion of the functional layer inserted into the groove.

20. The electronic device of claim 19, wherein the electronic device includes a smartphone, a tablet computer, a laptop, a television, a computer monitor, a smart glass, a smartwatch, a head-mounted display, or a vehicle.
